(19) United States
(12) Patent Application Publication
(10) Pub. No.: US 2019/0252180 A1
(43) Pub. Date: Aug. 15, 2019

(54) WAFER MANUFACTURING METHOD AND WAFER

(71) Applicant: SUMCO CORPORATION, Tokyo (JP)

(72) Inventors: Toshiyuki TANAKA, Tokyo (JP); Satoshi MATAGAWA, Tokyo (JP)

(73) Assignee: SUMCO CORPORATION, Tokyo (JP)

(21) Appl. No.: 16/345,080

(22) PCT Filed: Oct. 5, 2017
(86) PCT No.: PCT/JP2017/036313

§ 371 Date: Apr. 25, 2019

(30) Foreign Application Priority Data
Oct. 31, 2016 (JP) 2016-212775

(51) Int. Cl. H01L 21/02

(52) U.S. Cl. CPC H01L 21/02013; H01L 21/02024; H01L 21/02118; H01L 21/02021

(57) ABSTRACT

A wafer manufacturing method includes: a chamfering step of chamfering a wafer that is cut out from a monocrystal ingot and optionally lapped; a resin layer forming step of coating one surface of the chamfered wafer with a curable resin to form a resin layer, a first surface-grinding step of performing a surface grinding on the other surface of the chamfered wafer while holding the one surface through the resin layer; a resin layer removing step; and a second surface-grinding step of performing a surface grinding on the one surface while holding the other surface. Provided that a calculated average roughness of a chamfered portion of the chamfered wafer is represented by Ra (nm) and a viscosity of the curable resin to be applied is represented by V (mPa·s), the curable resin is applied in a manner satisfying a formula (1) below in the resin layer forming step.

Ra×V≥2×10³ (1)

### TECHNICAL FIELD

The present invention relates to a wafer manufacturing method and a wafer.

### BACKGROUND ART

In a semiconductor device manufacturing process, many layers of metallic and insulating films are formed on a wafer. Since uniformity of a film thickness of each of the layers formed on the wafer influences performance of the device, immediately after being formed, each of the layers is planarized by CMP (Chemical Mechanical Polishing). However, if the wafer has waviness, an accuracy of CMP would be decreased to form a layer having a non-uniform film thickness. The following planarization technique of the wafer having waviness has been typically known.

Firstly, one surface of the wafer is coated with a curable resin. The curable resin is planarized and cured to form a resin layer. Subsequently, while the planarized surface of the resin layer is held, the other surface of the wafer is ground to be planarized. After removing the resin layer or without removing the resin layer, the one surface of the wafer is ground to be planarized while the other planarized surface is held. It should be noted that the above technique is sometimes referred to as “resin application grinding” hereinafter.

An improvement in application of the above resin application grinding has been studied for a further planarization (see, for instance, Patent Literatures 1 to 4).

Patent Literature 1 discloses that a curable resin is applied in a thickness ranging from 40 μm to less than 300 μm.

Patent Literature 2 discloses that a curable resin having specific properties is applied in a thickness ranging from 10 μm to 200 μm. Patent Literature 2 also discloses that the curable resin in an uncured state has a viscosity ranging from 1000 mPa·s to 50000 mPa·s from a viewpoint of a working performance of the curable resin when the curable resin is applied.

Patent Literature 3 discloses that, while one surface of the wafer is held by suction to correct waviness of the wafer and the other surface of the wafer is ground and subsequently the one surface is ground while the other surface is held by suction, which causes similar grinding deformation to be formed on both the surfaces, and subsequently are subjected to resin application grinding.

Patent Literature 4 discloses that resin application grinding is repeatedly conducted.

### CITATION LIST

### Patent Literature(S)

Patent Literature 1: JP 2006-269761 A
Patent Literature 2: JP 2009-272557 A
Patent Literature 3: JP 2011-249652 A
Patent Literature 4: JP 2015-8247 A

### SUMMARY OF THE INVENTION

### Problem(s) to be Solved by the Invention

In the above resin application grinding, since the curable resin when being applied has fluidity, a portion of the curable resin for supporting a peripheral portion of the wafer may flow out beyond the wafer.

Since the flowing-out of the curable resin at the peripheral portion of the wafer is not taken into consideration in the methods of Patent Literatures 1 to 4, due to an influence by this flowing-out of the curable resin, a portion on a planarized surface of a resin layer, which corresponds to the peripheral portion of the wafer, cannot keep flatness. Accordingly, even if both the surfaces of the wafer are ground, waviness of the wafer may not be sufficiently decreased. If waviness of the wafer cannot be sufficiently decreased by the resin application grinding, the wafer cannot be sufficiently planarized even after both the surfaces of the wafer are mirror-polished, or a variation in flatness among a plurality of wafers may be increased.

An object of the invention is to provide a wafer manufacturing method capable of: providing a wafer sufficiently planarized after being mirror-polished; and decreasing a variation in flatness among a plurality of wafers, and the wafer.

### Means for Solving the Problem(s)

The inventors have attained the following findings as a result of dedicating themselves to study.

When a viscosity of a curable resin when the curable resin is applied is large, fluidity of the curable resin is decreased. Accordingly, it is expected that the curable resin at a peripheral portion of a wafer is unlikely to flow out. When a chamfered portion of the wafer is coarse, it is expected that adhesion of the curable resin to the chamfered portion is improved.

The inventors have found that the flow-out of the curable resin beyond the wafer is preventable and flatness of the entire planarized surface of the resin layer is maintainable by optimizing a relationship between a viscosity of the curable resin and roughness of the chamfered portion. The inventors have also found that grinding of both surfaces of the wafer can sufficiently decrease waviness at the peripheral portion of the wafer and that mirror-polishing of both the surfaces of the wafer having sufficiently decreased waviness can provide a sufficiently planarized wafer, thereby decreasing a variation in flatness among a plurality of wafers.

The invention has been achieved on the basis of the above-described findings.

According to an aspect of the invention, a wafer manufacturing method includes: a chamfering step of chamfering a wafer that is cut out from a monocrystal ingot and optionally lapped; a resin layer forming step of coating one surface of the chamfered wafer with a curable resin to form a resin layer; a first surface-grinding step of performing a surface grinding on the other surface of the chamfered wafer while holding the one surface through the resin layer; a resin layer removing step of removing the resin layer; and a second surface-grinding step of performing a surface grinding on the one surface while holding the other surface. Provided that a calculated average roughness of a chamfered portion of the chamfered wafer is represented by Ra (nm) and a viscosity of the curable resin when the curable resin is applied is represented by V (mPa·s), the curable resin is applied in a manner satisfying a formula (1) below in the resin layer forming step,

Ra×V≥2×10³ (1)

In the above aspect of the invention, since the viscosity V of the curable resin when the curable resin is applied (hereinafter, simply referred to as a “coating viscosity V”) and a calculated average roughness Ra of the chamfered portion (hereinafter, simply referred to as a “chamfering roughness Ra”) are set so as to satisfy the formula (1), the flow-out of the curable resin beyond the wafer is preventable and flatness of the entire planarized surface of the resin layer is maintainable. Accordingly, waviness at the peripheral portion of the wafer can be sufficiently decreased by subjecting the wafer to the first surface-grinding step, the resin layer removing step, and the second surface-grinding step.

Moreover, the wafer is sufficiently planarized by mirror-polishing both surfaces of the wafer, and a variation in flatness among a plurality of wafers is decreased.

According to another aspect of the invention, a wafer has 0.90 nm/mm² or less of a maximum value of Shape Curvatures in a plurality of sites, the plurality of sites being obtained by equally dividing in a peripheral direction an annular region of a peripheral portion of the wafer, the Shape Curvatures being obtained by measuring the plurality of sites using a flatness measuring device Wafersight 2 (manufactured by KLA-Tencor Corporation) in High Order Shape mode.

In the above aspect of the invention, since the maximum value of Shape Curvatures (Shape Curvature-max) expressing a curve (waviness) of the wafer is 0.90 nm/mm² or less, the wafer having a sufficiently small waviness at the peripheral portion can be obtained. It should be noted that Shape Curvature means the maximum curvature of a quadratic approximate curve for a curve in a single site.

Moreover, by mirror-polishing both the surfaces of the wafer, the maximum value of ESFQR (ESFQR-max) expressing flatness of the peripheral portion of the wafer can be 10 nm or less and a variation in ESFQR-max among a plurality of wafers can be reduced.

### BRIEF DESCRIPTION OF DRAWING(S)

FIG. 1 is a flowchart of a wafer manufacturing method in a first exemplary embodiment of the invention.

FIG. 2A is an illustration explaining the wafer manufacturing method.

FIG. 2B is another illustration explaining the wafer manufacturing method.

FIG. 2C is still another illustration explaining the wafer manufacturing method.

FIG. 3A is a further illustration explaining the wafer manufacturing method, showing a state subsequent to the states shown in FIGS. 2A, 2B and 2C.

FIG. 3B is a still further illustration explaining the wafer manufacturing method, showing a state subsequent to the states shown in FIGS. 2A, 2B and 2C.

FIG. 3C is a still further illustration explaining the wafer manufacturing method, showing a state subsequent to the states shown in FIGS. 2A, 2B and 2C.

FIG. 4 is a graph showing results of Experiment 1 in Examples of the invention.

FIG. 5 is a graph showing results of Experiment 2 in the Examples, showing a relationship between the wafer manufacturing method and Shape Curvature-max.

FIG. 6 is a graph showing results of Experiment 2 in the Examples, showing a relationship between the wafer manufacturing method and ESFQR-max.

### DESCRIPTION OF EMBODIMENT(S)

An exemplary embodiment of the invention will be described with reference to the attached drawings.

### Wafer Manufacturing Method

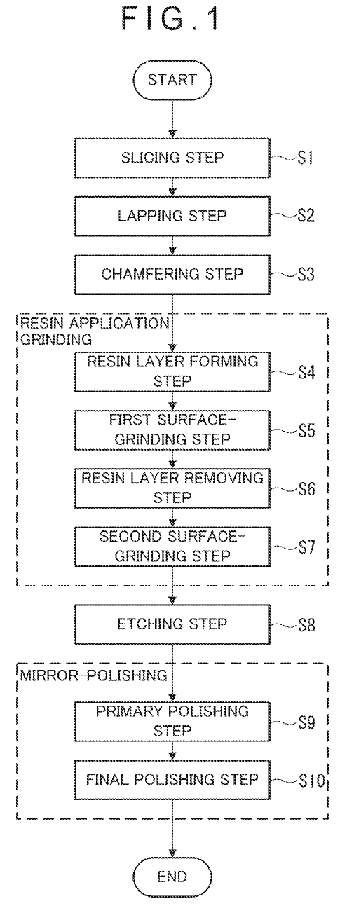

As shown in FIG. 1, in a wafer manufacturing method, firstly, a monocrystal ingot (hereinafter, simply referred to as an “ingot”) formed of, for instance, silicon, SiC, GaAs, or sapphire is cut with a wire saw to obtain a plurality of wafers (Step S1: slicing step).

Next, both surfaces of the wafer are simultaneously planarized (Step S2: lapping step) and chamfered (Step S3: chamfering step). A width of the chamfered portion (i.e., a distance from the outermost periphery of the wafer W to the outermost periphery of a non-chamfered portion of the wafer W) preferably ranges from 300 μm to 450 μm.

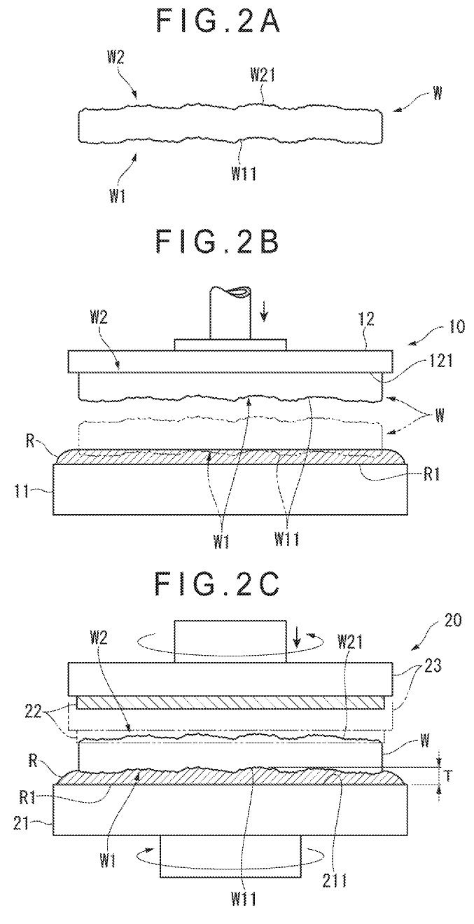

Since it is difficult to sufficiently planarize the wafer only at the lapping step, waviness W11, W21 are respectively generated on the one surface W1 and the other surface W2 of the obtained wafer W as shown in FIG. 2A.

Subsequently, a resin application grinding step is conducted as shown in FIG. 1. The resin application grinding step includes: a resin layer forming step (Step S4) of coating the one surface W1 of the wafer W with a curable resin to form a resin layer R (see FIG. 2B); a first surface-grinding step (Step S5) of performing a surface grinding on the other surface W2 of the wafer W while holding the one surface W1 through the resin layer R; a resin layer removing step (Step S6) of removing the resin layer R; and a second surface-grinding step (Step S7) of performing a surface grinding on the one surface W1 while holding the other surface W2.

In the resin layer forming step, a holding press device 10 as shown in FIG. 2B is used to form the resin layer R.

Firstly, the curable resin, which is to become the resin layer R, is dropped to be applied on a highly planarized plate 11.

At this time, a chamfering roughness Ra (i.e., a calculated average roughness Ra of the chamfered portion of the wafer W) and a coating viscosity V (i.e., a viscosity V of the curable resin when the curable resin is applied) satisfy a formula (1) below.

Ra×V≥2×10³ (1)

In order to satisfy the formula (1), the curable resin may be selected by its type so that the coating viscosity V reaches a predetermined value on the basis of the chamfering roughness Ra. Alternatively, the wafer may be chamfered so that the chamfering roughness Ra reaches a predetermined value on the basis of the coating viscosity V determined by the type of the used curable resin.

Since the chamfering roughness Ra influences stock removal for a damage removal in a back-end process, the chamfering roughness Ra is preferably 100 nm (1000 Å) or less when measured at a measurement distance of 200 μm and a cut-off wavelength of 20 μm.

The coating viscosity V is preferably 2000 mPa-s or less in order to obtain flatness of the entire planarized surface R1 of the resin layer R.

As shown by a solid line in FIG. 2B, a holding surface 121 of a holder 12 holds the other surface W2 of the wafer W by suction.

Next, the holder 12 is lowered, whereby the one surface W1 of the wafer W is pressed onto the curable resin as shown by a chain double-dashed line in FIG. 2B. Subsequently, the holder 12 releases the pressure applied to the wafer W to keep the wafer W from being elastically deformed. In such a state, the curable resin is cured on the one surface W1. According to the above steps, the curable resin becomes the resin layer R in which a surface of the curable resin opposite a surface in contact with the one surface W1 is defined as a planarized surface R1.

Examples of a method of coating the wafer W with the curable resin include: spin coating of placing the wafer W with the one surface W1 facing up, dropping the curable resin onto the one surface W1, and rotating the wafer W to spread the curable resin over the entire one surface W1; screen printing of placing a screen mask over the one surface W1, putting the curable resin on the screen mask and coating the one surface W1 with the curable resin using a squeegee; and electric spray deposition of spraying the curable resin over the entire one surface W1. After the curable resin is applied over the entire one surface W1, the highly planarized plate 11 is pressed onto the curable resin. For instance, a photosensitive resin is preferable as the curable resin since the photosensitive resin is easily peelable after the processing. Particularly, the photosensitive resin is suitable since not receiving thermal stress. In the exemplary embodiment, a UV curable resin is used as the curable resin. Another specific example of a material of the curable resin is an adhesive (e.g., wax).

In the first surface-grinding step, the other surface W2 is ground using a surface grinder 20 as shown in FIG. 2C.

Firstly, the wafer W with the planarized surface R1 facing down is placed on a holding surface 211, which is highly planarized, of a vacuum chuck table 21. Subsequently, the vacuum chuck table 21 holds the wafer W by suction.

Next, a surface plate 23 provided with a grinding stone 22 on a lower surface is moved above the wafer W as shown by a solid line in FIG. 2C. Subsequently, while the surface plate 23 is lowered with rotation, the vacuum chuck table 21 is rotated. The grinding stone 22 is brought into contact with the other surface W2 as shown by a chain double-dashed line in FIG. 2C, thereby performing a surface grinding on the other surface W2. When a stock removal is equal to or more than the minimum stock removal P, the surface grinding ends. According to the above steps, the other surface W2 becomes a planarized surface in which waviness is sufficiently removed.

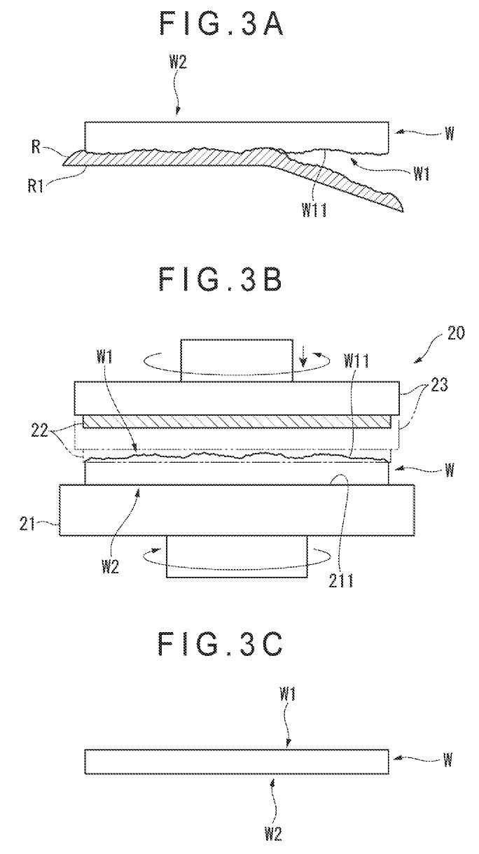

In the resin layer removing step, the resin layer R formed on the one surface W1 of the wafer W is pulled off from the wafer W as shown in FIG. 3A. In this step, the resin layer R may be chemically removed using a solvent.

In the second surface-grinding step, the one surface W1 is ground using the same surface grinder 20 as in the first surface-grinding step as shown in FIG. 3B.

Firstly, the wafer W is placed on the holding surface 211 with the highly planarized surface W2 facing down. Subsequently, the vacuum chuck table 21 holds the wafer W by suction. While the surface plate 23 having being moved above the wafer W as shown by a solid line in FIG. 3B is lowered with rotation, the vacuum chuck table 21 is rotated, thereby performing a surface grinding on the one surface W1 as shown by a chain double-dashed line in FIG. 3B. When a stock removal is equal to or more than the minimum stock removal P, the surface grinding ends, so that the one surface W1 becomes a planarized surface in which waviness is sufficiently removed.

According to the above resin application grinding step, the wafer W having the one surface W1 and the other surface W2 so highly planarized as shown in FIG. 3C in which waviness W11, W21 is sufficiently removed is obtained.

An annular region of a peripheral portion of the obtained wafer W is equally divided in a peripheral direction into a plurality of sites. Shape curvature-max at the plurality of sites is measured using a flatness measuring device Wafersight 2 (manufactured by KLA-Tencor Corporation) in High Order Shape mode. The obtained wafer W is characterized by having Shape Curvature-max of 0.90 nm/mm² or less.

Next, as shown in FIG. 1, the wafer W is etched in order to remove an affected layer generating on the wafer W at the chamfering and the resin application grinding step and remaining on the wafer W afterward (Step S8: etching step).

Subsequently, the wafer W is subjected to mirror-polishing including: a primary polishing step (Step S9) in which both the surfaces of the wafer W are polished using a double-side polisher; and a final polishing step (Step S10) in which both the surfaces of the wafer W are polished using a single-side polisher. The wafer manufacturing method ends by the mirror-polishing.

The wafer W obtained after the mirror-polishing has ESFQR-max of 10 nm or less. A variation in ESFQR-max among a plurality of wafers W is reduced.

### Advantage(s) of Exemplary Embodiment(s)

Since the resin layer forming step is conducted under the conditions satisfying the formula (1) as described above, a portion of the curable resin for supporting the peripheral portion of the wafer W is prevented from flowing out beyond the wafer W, so that flatness of the entire planarized surface R1 of the resin layer R is maintained. Accordingly, by subjecting the thus obtained wafer W to the first surface-grinding step, the resin layer removing step, and the second surface-grinding step, waviness W11, W21 at the respective peripheral portions of the one surface W1 and the other surface W2 can be sufficiently removed. Moreover, by being mirror-polished, the wafer W can be sufficiently planarized and have less variation in flatness from other wafers W.

### Modification(s)

The invention is not limited to the above exemplary embodiment but any improvement and design change are possible without departing from the scope of the present disclosure. Moreover, the specific procedure and configuration for implementing the invention may be any procedures and configurations without departing from the scope of the present disclosure.

For instance, in some embodiments, the lapping step is not conducted and the resin application grinding step is conducted at least under the conditions satisfying the formula (1). Even in this case, the wafer W having the above characteristics can be obtained.

Moreover, in some embodiments, the resin layer R is removed not by being pulled off but by being ground at the second surface-grinding step also serving as the resin layer removing step.

### EXAMPLE(S)

Next, the invention will be described more in detail by Examples, however, by no means limited to the Examples.

### Experiment 1: Study on Allowable Range of Ra×V

### Wafer Manufacturing Method

Firstly, UV curable resins A to C were prepared. The resins A to C respectively exhibited 150 mPa·s, 320 mPa·s and 700 mPa·s in terms of the coating viscosity V as shown in Table 1.

A monocrystal ingot was subjected to a slicing step shown in FIG. 1 to prepare wafers each having a diameter of 300 mm and a thickness of about 900 μm.

Next, the wafers were subjected to the chamfering step and the resin application grinding step.

In the chamfering step, chamfering conditions were adjusted so as to obtain the wafers having the chamfering roughness Ra shown in Table 1. The width of the chamfered portion of each wafer was determined at 400 μm.

The chamfering roughness Ra was obtained by measuring roughness at a plurality of portions in a peripheral direction in the chamfered portion using a surface roughness measuring device (manufactured by Chapman Instruments) and calculating the average of measurement results.

TABLE 1

| Coating | Chamfering | | | |
|---|---|---|---|---|
| Viscosity V | Roughness | | Ra × V ≥ | Shape Curvature − |
| (mPa · s) | Ra (nm) | Ra × V | 2 × 10³ | max (nm/mm²) |
| 150 | 5.1 | 765 | NG | 1.40 |
| (Resin A) | | | | 1.32 |
| | 7.3 | 1095 | NG | 1.18 |
| | | | | 1.21 |
| | 12.1 | 1815 | NG | 0.97 |
| | | | | 1.05 |
| | 28.0 | 4200 | OK | 0.79 |
| | | | | 0.86 |
| | 53.3 | 7995 | OK | 0.71 |
| | | | | 0.73 |
| 320 | 1.6 | 512 | NG | 1.51 |
| (Resin B) | | | | 1.44 |
| | 3.4 | 1088 | NG | 1.32 |
| | | | | 1.22 |
| | 5.1 | 1632 | NG | 1.18 |
| | | | | 1.23 |
| | 7.3 | 2336 | OK | 0.88 |
| | | | | 0.83 |
| | 12.1 | 3872 | OK | 0.81 |
| | | | | 0.79 |
| 700 | 0.4 | 280 | NG | 1.98 |
| (Resin C) | | | | 2.11 |
| | 1.6 | 1120 | NG | 1.31 |
| | | | | 1.25 |
| | 3.4 | 2380 | OK | 0.87 |
| | | | | 0.81 |
| | 5.1 | 3570 | OK | 0.69 |
| | | | | 0.77 |
| | 7.3 | 5110 | OK | 0.57 |
| | | | | 0.65 |

In the resin layer forming step, the wafer having a chamfering roughness Ra of 5.1 nm was coated with the resin A and cured by UV radiation to form a resin layer having a resin thickness of 100 μm. The product of the chamfering roughness Ra and the coating viscosity V was 765 as shown in Table 1, which did not satisfy the formula (1) (expressed by “NG” in Table 1).

The rest of the wafers were coated with the resins A to C in combinations as shown in Table 1 to form the resin layers each having a resin thickness of 100 μm. “OK” in Table 1 means that the product of the chamfering roughness Ra and the coating viscosity V satisfies the formula (1).

Next, the wafers provided with the respective resin layers were subjected to the first surface-grinding step, the resin layer removing step, and the the second surface-grinding step. In the first and second surface-grinding steps, the wafers were ground at a stock removal of 20 μm using a grinder (DFG8000 series) manufactured by DISCO Corporation.

Subsequently, the wafers were subjected to etching step, mirror-polishing step, and cleaning step. In the mirror-polishing step: both surfaces of each wafer were polished in a range from 5 μm to 20 μm in total using a double-side polisher at the primary polishing step; and only one of the surfaces of each wafer was polished at less than 1 μm at the final polishing step.

### Evaluation

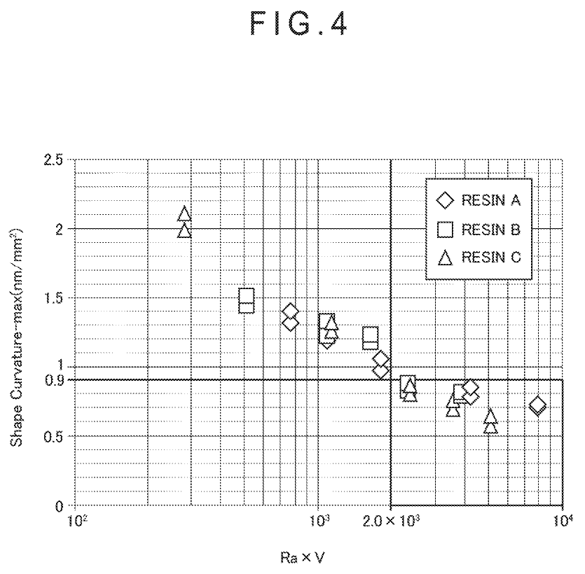

A shape of the peripheral portion of each wafer was measured using a flatness measuring device Wafersight 2 (manufactured by KLA-Tencor Corporation) in High Order Shape mode. The peripheral portion of each wafer was measured in terms of an annular region enclosed by circles at 2 mm and 32 mm away from the outermost periphery of the wafer in the center direction of the wafer (i.e., a 30-mm wide annular region except for a 2-mm edge of the outermost periphery of the wafer). The annular region was equiangularly divided into 72 sites. The maximum value in the 72 sites in terms of shape curvature was evaluated as Shape Curvature-max. The evaluation results are shown in Table 1 and FIG. 4.

It has been found that the larger product of Ra and V leads to the smaller Shape Curvature-max irrespective of the value of V as shown in FIG. 4. It has also been found that, when the formula (1) is satisfied, the obtained wafer has Shape Curvature-max of 0.90 nm/mm² or less which shows sufficiently small waviness.

### Experiment 2: Relationship of Wafer Manufacturing Method to Shape Curvature-Max and ESFQR-Max

### Wafer Manufacturing Method

### Example 1

Ten wafers were obtained through the steps (i.e., the slicing step, chamfering step, resin application grinding step, etching step, mirror-polishing step, and cleaning step) conducted under the same conditions as in Experiment 1 except for the coating viscosity V of the curable resin and the chamfering roughness Ra of the chamfered portion. The coating viscosity V and the chamfering roughness Ra were set so as to satisfy the formula (1).

### Comparative 1

19 wafers were obtained through the steps (i.e., the slicing step, lapping step, chamfering step, first surface-grinding step, second etching step, mirror-polishing step, and cleaning step) conducted under the same conditions as in Experiment 1 except that the lapping step was conducted between the slicing step and the chamfering step, and only the first and second surface-grinding steps were conducted between the chamfering step and the etching step.

### Comparative 2

Five wafers were obtained through the steps (i.e., the slicing step, chamfering step, resin application grinding step, etching step, mirror-polishing step, and cleaning step) conducted under the same conditions as in Example 1 except that the coating viscosity V and the chamfering roughness Ra were set so as not to satisfy the formula (1).

### Comparative 3

Five wafers were obtained through the steps (i.e., the slicing step, chamfering step, primary grinding step, resin application grinding step, etching step, mirror-polishing step, and cleaning step) conducted under the same conditions as in Comparative 2 except that the primary grinding step was conducted between the chamfering and the resin application grinding step. The primary grinding step, which corresponds to a primary grinding step disclosed in JP 2011-249652 A, is a step for removing deformation caused by processing on both surfaces of each wafer.

### Evaluation: Shape Curvature-Max

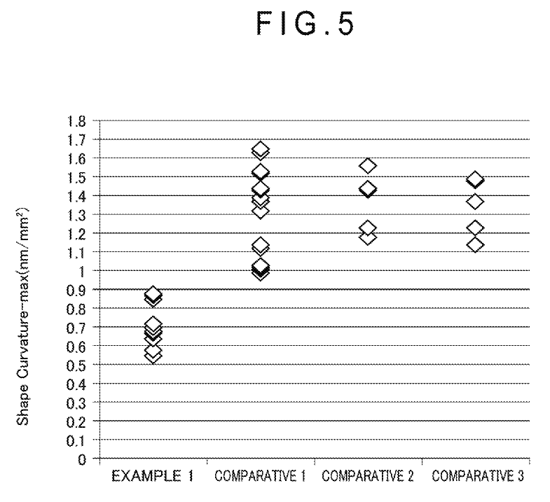

The wafers in Example 1 and Comparatives 1 to 3 were evaluated in terms of Shape Curvature-max in the same manner as in Experiment 1. The evaluation results are shown in FIG. 5.

It was found as shown in FIG. 5 that a variation in Shape Curvature-max was larger in Comparative 1, in which no resin application grinding step was performed, than in Example 1 and Comparatives 2 and 3 with the resin application grinding step. Moreover, it was found that Shape Curvature-max was 0.90 nm/mm² or less in Example 1 where the resin application grinding step was conducted under the conditions satisfying the formula (1) while Shape Curvature-max exceeded 0.90 nm/mm² in Comparatives 1 to 3 where the formula (1) was not satisfied.

### ESFQR-Max

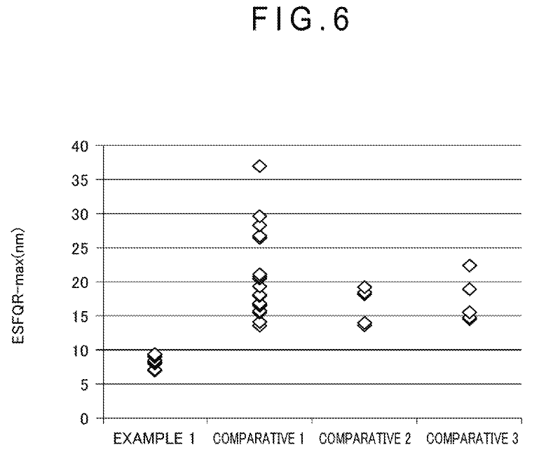

In each of the wafers of Example 1 and Comparatives 1 to 3, 72 sites used for evaluation of Shape Curvature-max were measured in terms of SFQR. The maximum value in the measurement results was obtained as ESFQR-max. The evaluation results are shown in FIG. 6. ESFQR-max was measured using a flatness measuring device Wafersight 2 (manufactured by KLA-Tencor Corporation).

As shown in FIG. 6, it was found that ESFQR-max was 10 nm or less in Example 1 where the resin application grinding step was conducted under the conditions satisfying the formula (1) while ESFQR-max exceeded 10 nm in Comparatives 1 to 3 where the formula (1) was not satisfied. It was also found that a variation in ESFQR-max was smaller in Example 1 than in Comparatives 1 to 3.

### Outline

In Experiments 1 and 2 described above, the wafers were evaluated after the mirror-polishing step. However, it can be estimated that Shape Curvature-max after the resin application grinding step (after the second surface-grinding step in Comparative 1) and before the etching step is also approximately equal to those shown in FIGS. 4 and 5. This is because the stock removal in the etching step and the mirror-polishing step is extremely smaller than those in the lapping step and the resin application grinding step, and accordingly, the shape of each wafer after the mirror-polishing step is substantially the same as that immediately after the resin application grinding step.

For this reason, it can be estimated that, when the resin application grinding step is conducted under the conditions satisfying the formula (1), Shape Curvature-max obtained immediately after the resin application grinding step is 0.90 nm/mm² or less. It has been confirmed that, when the wafer having the above characteristics is mirror-polished, ESFQR-max is 10 nm or less and a variation of ESFQR-max is decreased. In other words, it has been confirmed that the wafer sufficiently planarized is obtained after the mirror-polishing, and a variation in flatness among a plurality of wafers is decreased.

### EXPLANATION OF CODE(S)

R . . . resin layer, W . . . wafer, W1 . . . one surface, W2 . . . the other surface.

1. A wafer manufacturing method comprising:
a chamfering step of chamfering a wafer that is cut out from a monocrystal ingot and optionally lapped;
a resin layer forming step of coating one surface of the chamfered wafer with a curable resin to form a resin layer;
a first surface-grinding step of performing a surface grinding on the other surface of the chamfered wafer while holding the one surface through the resin layer;
a resin layer removing step of removing the resin layer; and
a second surface-grinding step of performing a surface grinding on the one surface while holding the other surface, wherein
provided that a calculated average roughness of a chamfered portion of the chamfered wafer is represented by Ra (nm) and a viscosity of the curable resin when the curable resin is applied is represented by V (mPa·s), the curable resin is applied in a manner satisfying a formula (1) below in the resin layer forming step.
Ra×V≥2×10³ (1)

2. A wafer comprising 0.90 nm/mm² or less of a maximum value of Shape Curvatures in a plurality of sites, the plurality of sites being obtained by equally dividing in a peripheral direction an annular region of a peripheral portion of the wafer, the Shape Curvatures being obtained by measuring the plurality of sites using a flatness measuring device Wafersight 2 (manufactured by KLA-Tencor Corporation) in High Order Shape mode.
